(19) United States
(12) Patent Application Publication
(10) Pub. No.: US 2026/0165124 A1
(43) Pub. Date: Jun. 11, 2026

(54) POWER MODULE WITH PAIRED-SWITCH ARCHITECTURE AND EMBEDDED CAPACITORS

(71) Applicant: North Carolina State University, Raleigh, NC (US)

(72) Inventor: Wensong Yu, Raleigh, NC (US)

(21) Appl. No.: 19/411,951

(22) Filed: Dec. 8, 2025

Related U.S. Application Data
(60) Provisional application No. 63/729,739, filed on Dec. 9, 2024.

(51) Int. Cl. H10W 40/20; H05K 1/02

(52) U.S. Cl. CPC H10W 40/235; H05K 1/0203; H05K 2201/064; H05K 2201/066; H05K 2201/10015; H05K 2201/10053; H05K 2201/10545

(57) ABSTRACT

Various examples are provided related to power modules with paired-switch architecture and embedded capacitors. In one example, a power module includes a plurality of paired switches; a printed circuit board (PCB) including parasitic flying capacitor elements within a thin polyimide dielectric layer, the parasitic flying capacitor elements extending between adjacent paired switches; and first and second cooling plates on opposite sides of the plurality of paired switches on the thin polyimide dielectric layer. Each of the paired switches can include first and second switches on opposite sides of the polyimide dielectric layer with at least a portion of the first and second switches extending over each adjacent parasitic flying capacitor element.

### CROSS REFERENCE TO RELATED APPLICATIONS

This application claims priority to, and the benefit of, U.S. provisional application entitled “Power Module with Paired-Switch Architecture and Embedded Capacitors” having Ser. No. 63/729,739, filed Dec. 9, 2024, which is hereby incorporated by reference in its entirety.

### BACKGROUND

Wide bandgap semiconductors including silicon carbide (SiC) devices have become prime candidates for high-performance power electronics due to their high breakdown voltage, low switching loss, and high-temperature operation. However, conventional packaging techniques limit the performance of SiC power modules because of parasitic inductance and heat dissipation issues.

### SUMMARY

Aspects of the present disclosure are related to power modules with paired-switch architecture and embedded capacitors. In one aspect, among others, a power module comprises a plurality of paired switches; a printed circuit board (PCB) comprising parasitic flying capacitor elements disposed within a thin polyimide dielectric layer, the parasitic flying capacitor elements extending between adjacent paired switches, where each of the paired switches comprises first and second switches disposed on opposite sides of the polyimide dielectric layer with at least a portion of the first and second switches extending over each adjacent parasitic flying capacitor element; and first and second cooling plates disposed on opposite sides of the plurality of paired switches disposed on the thin polyimide dielectric layer. In one or more aspects, each of the first and second switches can comprise a local gate driver disposed on the PCB between adjacent first switches or adjacent second switches. The PCB can comprise supporting layers disposed on opposite sides of the thin polyimide dielectric layer between the plurality of paired switches, the local gate drivers disposed on the supporting layers. The supporting layers can comprise polyimide.

In various aspects, the plurality of paired switches can be disposed on the thin polyimide dielectric layer in a rectangular array. The plurality of paired switches can be mounted to the PCB using high temperature soldering. The plurality of paired switches can be coupled to the first and second cooling plates by low temperature soldering. The power module can be potted with silicone gel. The first and second cooling plates can be metalized ceramic cooling plates. The first and second cooling plates can be liquid cooled. In some aspects, the parasitic flying capacitor elements can be metallic plates embedded in the thin polyimide dielectric layer. The plurality of paired switches can comprise high power SiC switches. Adjacent paired switches can be separated by a distance in a range from about 0.1 mm to about 0.2 mm. The plurality of paired switches can be connected in parallel, in series, or a combination of parallel and series connections. A thickness of the thin polyimide dielectric layer can be in a range between about 0.05 mm and about 0.15 mm. The plurality of paired switches can comprise N paired switches including 2N power semiconductor switches disposed on opposite sides of the polyimide dielectric layer. The 2N power semiconductor switches can comprise silicon carbide (SiC) devices.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1C are various views illustrating an example of a power module, in accordance with various embodiments of the present disclosure.

FIGS. 2A-2C are various views illustrating an example of a metalized ceramic liquid cooling plate, in accordance with various embodiments of the present disclosure.

FIG. 3 illustrates an example of an arrangement of paired-switches on a PCB of a power module, in accordance with various embodiments of the present disclosure.

FIGS. 4A-4C are various views illustrating dimensions and characteristics of the paired-switch layout, in accordance with various embodiments of the present disclosure.

FIG. 5 illustrates an example of local gate driver positioning for the switches, in accordance with various embodiments of the present disclosure.

FIGS. 6A-6C illustrate an example of a power module with embedded parasitic flying capacitors, in accordance with various embodiments of the present disclosure.

FIGS. 7A-7C illustrate examples of fabrication aspects of the power module, in accordance with various embodiments of the present disclosure.

### DETAILED DESCRIPTION

Disclosed herein are various examples related to power modules with paired-switch architecture and embedded capacitors. It would be beneficial to expand WGB power module capabilities to handle higher voltage and higher current while maintaining low cost and high reliability. Reference will now be made in detail to the description of the embodiments as illustrated in the drawings, wherein like reference numbers indicate like parts throughout the several views.

A high-power switching module packaging solution is proposed which includes a variety of innovations. Rather than using a bare die, the solution can use commercially available top-side cooled discrete devices to handle ultra-high voltage and ultra-high current, while leveraging the development and demonstration risks. An optimized back-to-back symmetric layout of multiple paired switches is designed with a very thin and complete polyimide dielectric layer to ensure 20 kV partial-discharge-free isolation, while maximizing parasitic DC flying-capacitance across the paired switches and minimizing parasitic commutation loop inductance, which reduces voltage overshoot across power switches (e.g., SiC switches) and power loss of snubber circuit for dynamic voltage balancing. A simple multi-level bootstrap power supply circuit can be co-designed with a high-voltage capacitive driving method to provide low-profile, distributed local gate drivers (e.g., SiC gate drivers) for synchronous and fast switching. Metalized ceramic liquid cooling plates can enable an extremely compact cooling design with capabilities of heat flux up to 600 W/cm² and dielectric insulation strength up to 20 kV, while eliminating the complicated assembly process of multi-layer different thermal and dielectric materials.

A power module can include a plurality of paired switches; a printed circuit board (PCB) comprising parasitic flying capacitor elements disposed within a thin polyimide dielectric layer, the parasitic flying capacitor elements extending between adjacent paired switches, where each of the paired switches comprises first and second switches disposed on opposite sides of the polyimide dielectric layer with at least a portion of the first and second switches extending over each adjacent parasitic flying capacitor element; and first and second cooling plates disposed on opposite sides of the plurality of paired switches disposed on the thin polyimide dielectric layer. 2N pieces of power semiconductors can be divided into N pieces of paired switches. In each of the paired switches, one switch is placed on top of another switch with a very thin dielectric layer between the two switches. Polyimide exhibits very high dielectric strength, typically in the range of 200-300 kV/mm depending on its formulation and thickness. The range for the thickness of the very thin polyimide dielectric layer can be between about 0.05 mm and about 0.15 mm for this application. N pieces of the paired switches can be connected in parallel, or in series, or hybrid, or not connected. Large conductive plates on each side of a very thin dielectric layer are designed to maximize the embedded decoupling/clamping/filtering capacitors across the paired switches.

This technology does not require expensive materials or complex manufacturing processes. Readily available surface mount devices that are manufactured at high volumes can be utilized. The design concepts are easily expanded to higher voltages up to 10,000V and higher currents up to 2,000 A. It is also more cost effective to achieve high blocking voltage through the use of multiple low voltage (LV) devices in series rather than through a single (and expensive) high voltage chip. Possible uses include, but are not limited to, gearbox-less medium voltage drives, utility scale inverters for renewables, solid-state transformers for data centers, and converters for flexible HVDC.

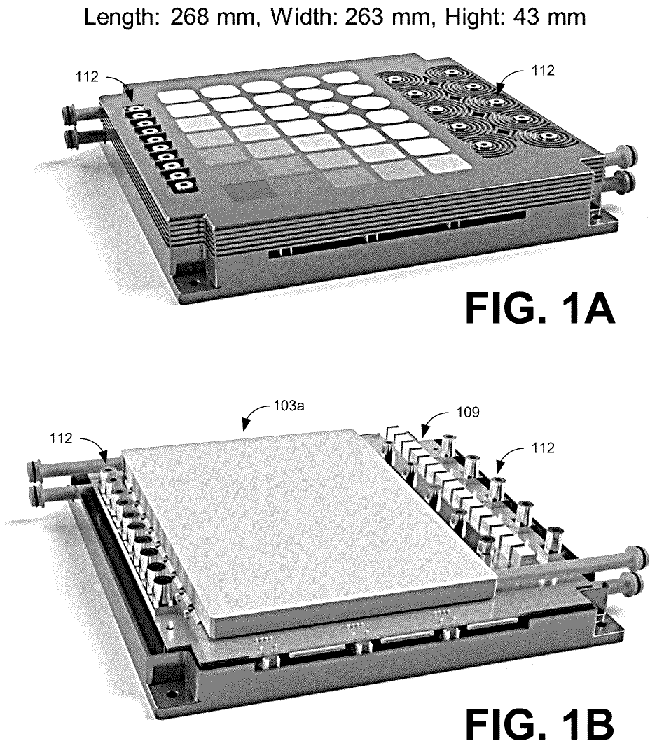

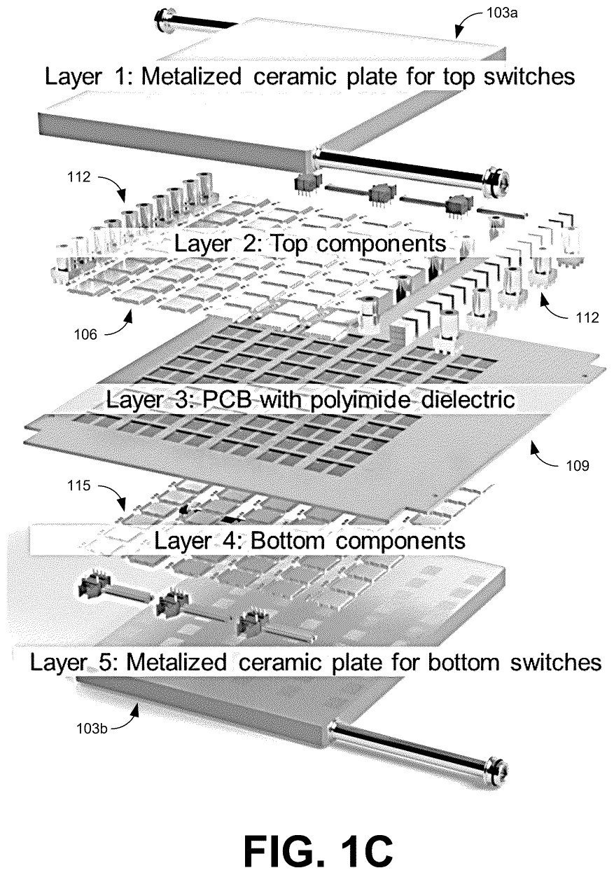

One example of an ultra-high power SiC power module with optimized parasitic inductance and heat dissipation is shown in FIGS. 1A, 1B and 1C. Shown are views of the encapsulated module in FIG. 1A, the module with the encapsulation removed in FIG. 1B, and an exploded view of the power module components in FIG. 1C. As illustrated in the exploded view of FIG. 1C, the power module can include a first layer (Layer 1) comprising a metalized ceramic plate 103a for top switches 106 on the PCB 109, a second layer (Layer 2) comprising top components (e.g., top switches 106, connectors 112, etc.), a third layer (Layer 3) comprising the PCB 109 with, e.g., polyimide dielectric, a fourth layer (Layer 4) comprising bottom components (e.g., bottom switches 115, etc.), and a fifth layer (Layer 5) comprising a metalized ceramic plate 103b for bottom switches on the PCB 109. FIG. 1B shows the assembled power module with the metalized ceramic plate 103a placed over the top switches 106 on the PCB 109. The connectors 112 extend through the encapsulation as shown in FIG. 1A. An example of the overall dimensions of encapsulated module is shown in FIG. 1A.

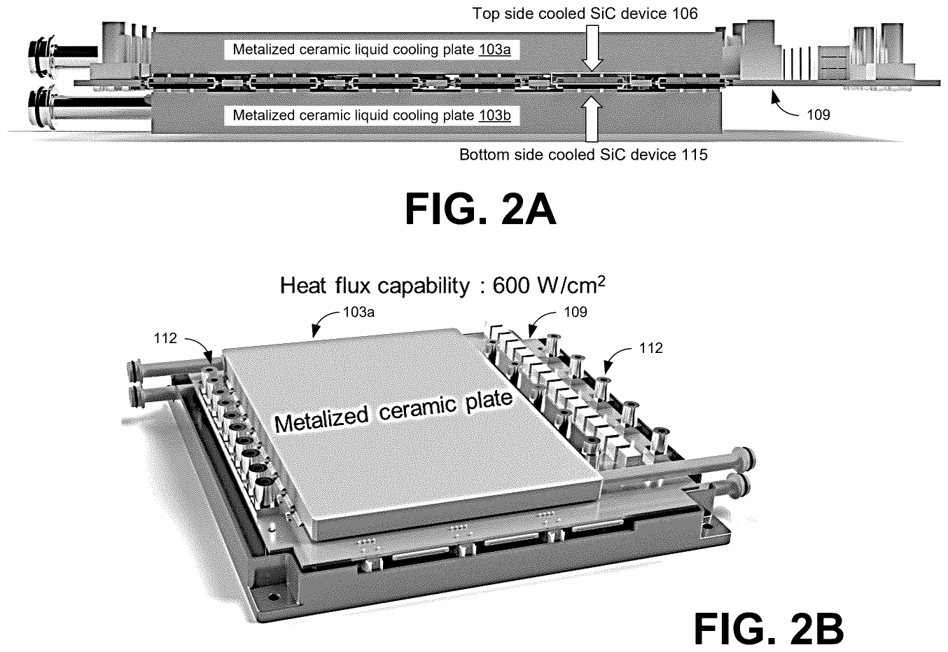

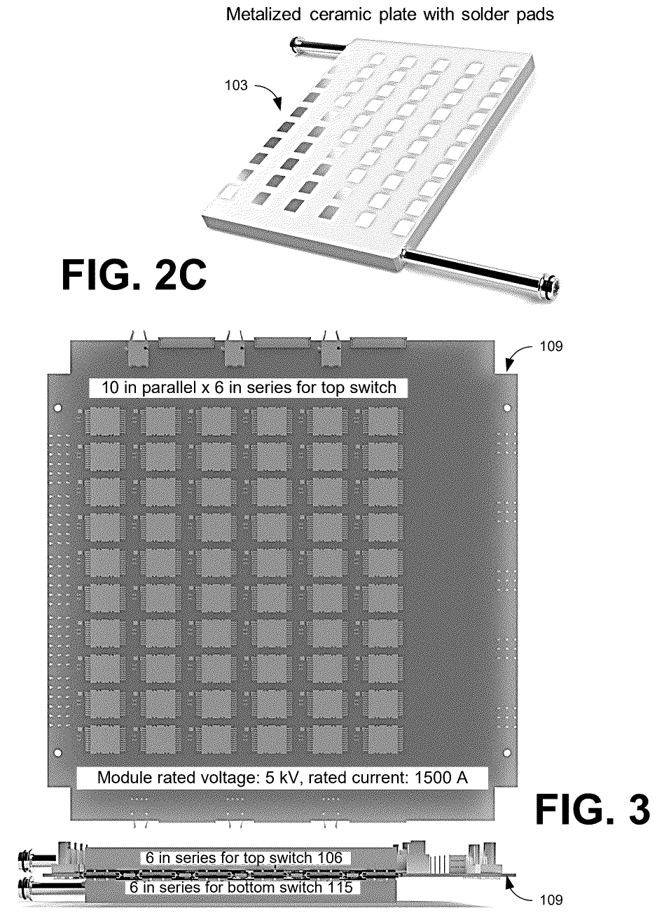

The proposed module design can include metalized ceramic cooling plates 103 on either side of a printed circuit board 109 which provide good heat dissipation to the top side cooled SiC devices 106 while also maintaining electrical isolation. FIG. 2A is a side view showing metalized ceramic liquid cooling plate 103a positioned against the top side switching devices 106 on the PCB 109 and the metalized ceramic liquid cooling plate 103b positioned against the bottom side switching devices 115 on the PCB 109. FIG. 2B is a perspective view illustrating the inlet and outlet connections for the liquid cooling. FIG. 2C illustrates an example of the arrangement of solder pads on a metalized ceramic liquid cooling plate 103. The metalized cooling plates 103 can increase the efficiency of the provided cooling.

The silicon carbide switches 106/115 can be arranged in multiple rows in parallel and multiple devices in series on BOTH sides of a very thin dielectric layer for a module to withstand higher voltage and higher current. A unit with 60 paired switches is shown in FIG. 3. The switching devices 106/115 are duplicated on the top and bottom of the PCB 109, separated by the very thin dielectric layer.

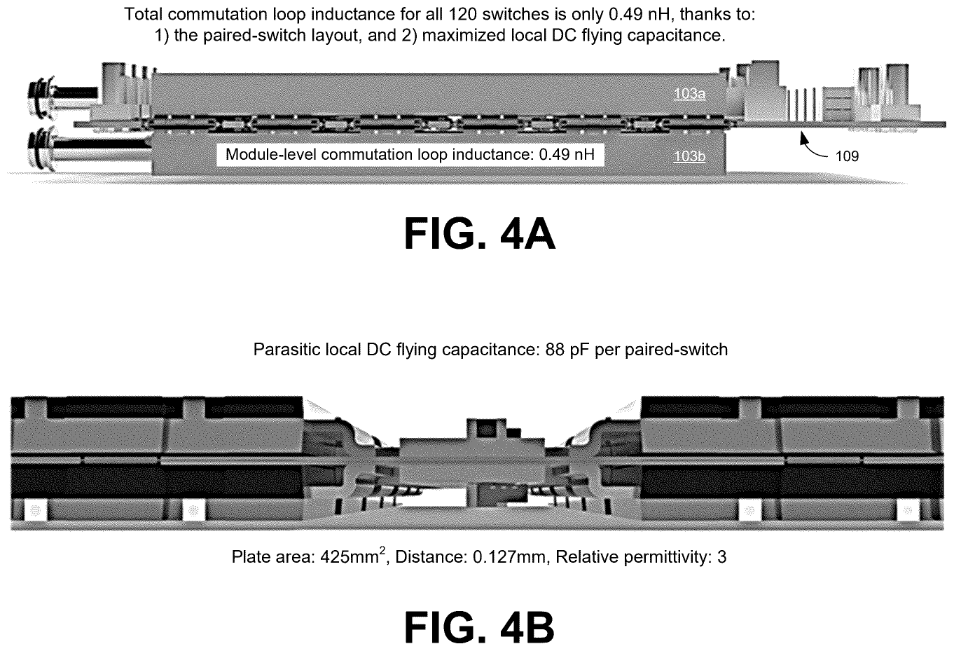

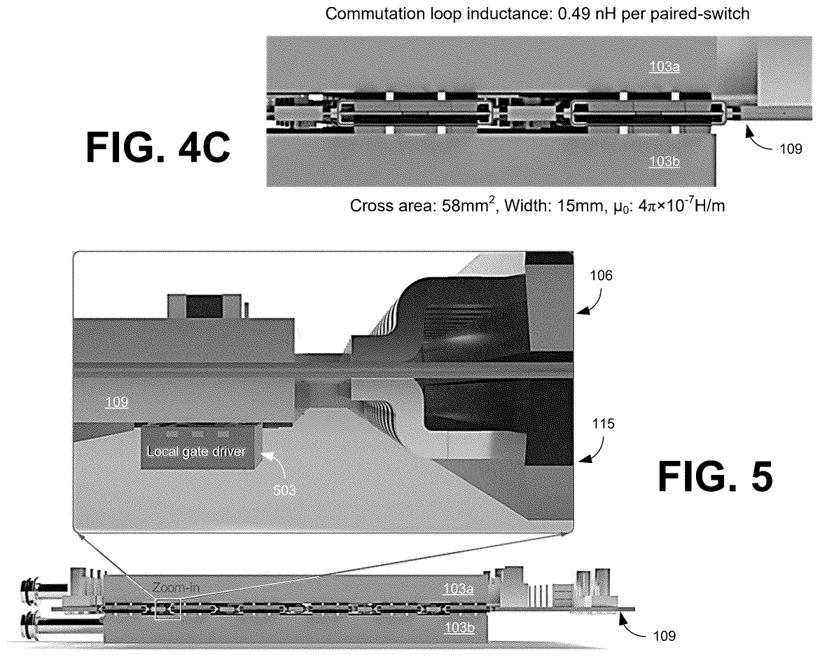

An improvement of more than 10× (from 10 s nH to less than 1) of total commutation loop inductance for the overall high-power module can be achieved by the proposed paired switch technology. For example, the total commutation loop inductance for the 120 switches is only 0.49 nH in the example of FIG. 4A, which may be attributed to the paired-switch layout and the maximized local DC flying capacitance. FIGS. 4B and 4C illustrate dimensions and characteristics of the module layout, which results in a parasitic local DC flying capacitance of about 88 pF per paired-switch.

Local gate driver ICs can be connected directly to the power semiconductor switches 106/115. FIG. 5 provides an exploded view showing the local gate driver 503 positioned on the PCB 109 adjacent to the switches 106/115. This can enable high speed switching with reduced losses. The local gate drivers can be located on support layers disposed between the paired switches illustrated.

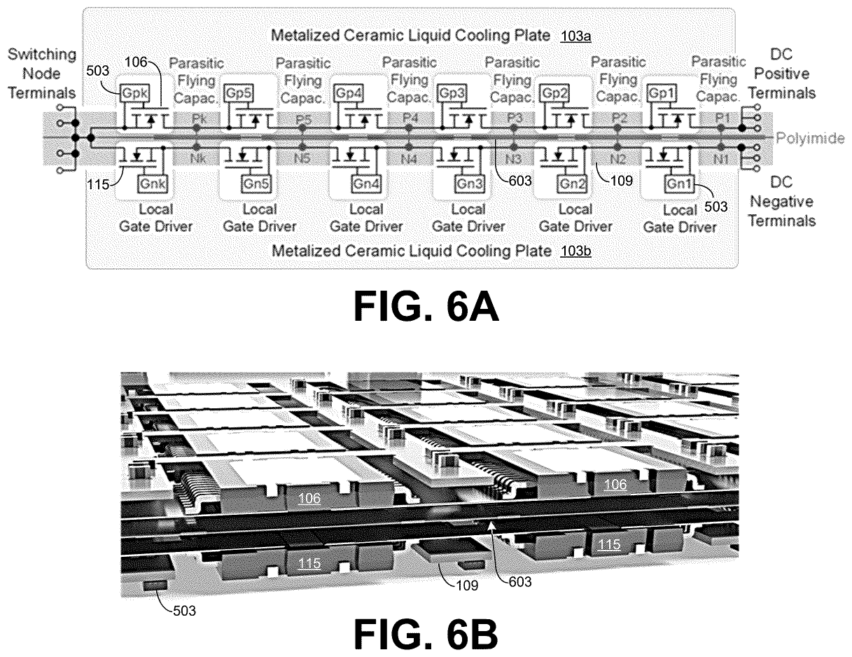

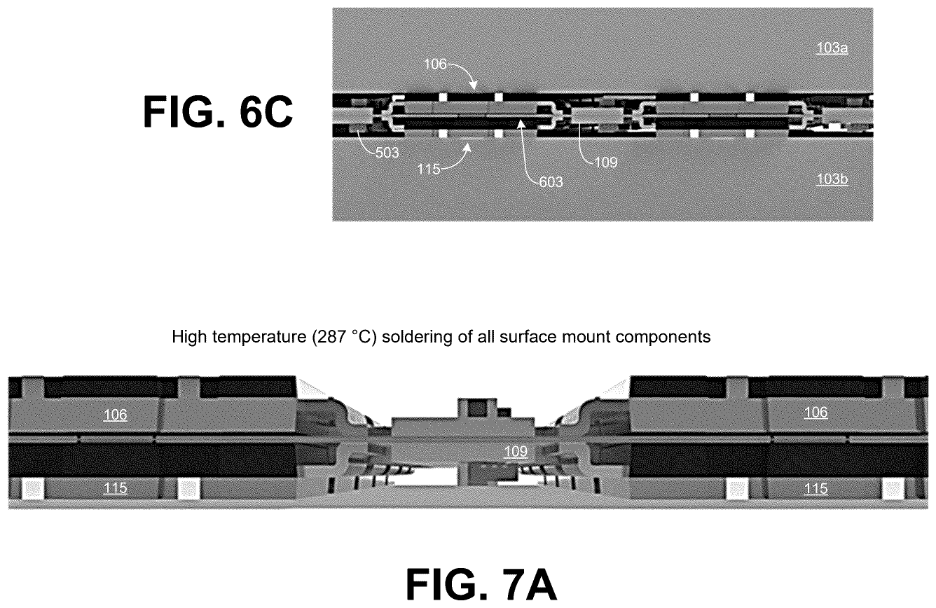

A more detailed schematic diagram of a power module with embedded parasitic flying capacitors 603 is shown in FIG. 6A with exploded and side cross-section views in FIGS. 6B and 6C, respectively. The parasitic flying capacitive elements 603 extend between the switches 106/115.

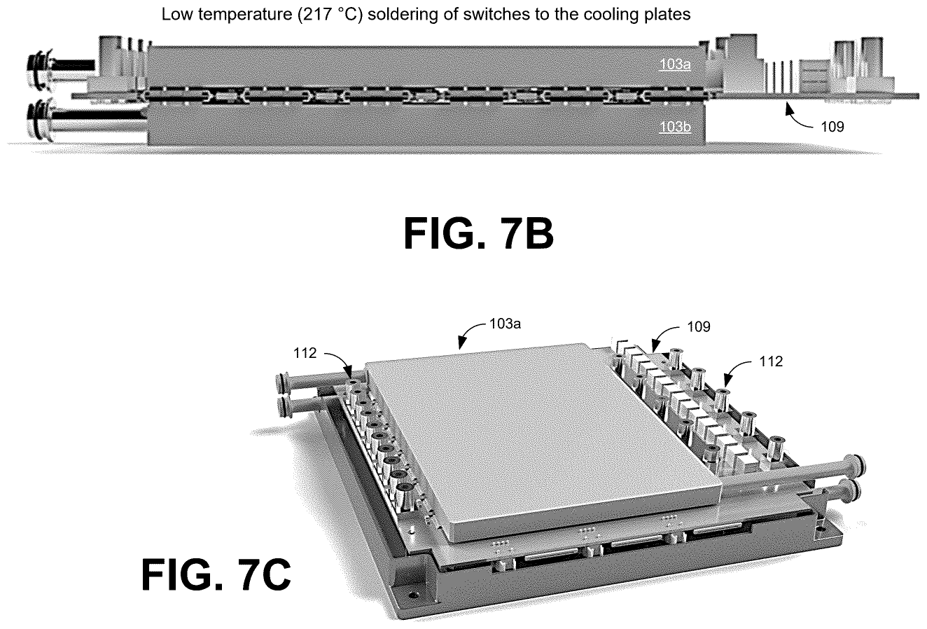

The proposed power module can follow a standard manufacturing process as generally performed on the printed circuit board population. For example, high temperature soldering of all surface mount components can be performed as illustrated in FIG. 7A, followed by low temperature soldering of switches 106/115 to the cooling plates 103a/103b as illustrated in FIG. 7B. Silicone gel can be used for potting the full assembly as shown in FIG. 7C.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

1. A power module, comprising:
a plurality of paired switches;
a printed circuit board (PCB) comprising parasitic flying capacitor elements disposed within a thin polyimide dielectric layer, the parasitic flying capacitor elements extending between adjacent paired switches, where each of the paired switches comprises first and second switches disposed on opposite sides of the polyimide dielectric layer with at least a portion of the first and second switches extending over each adjacent parasitic flying capacitor element; and
first and second cooling plates disposed on opposite sides of the plurality of paired switches disposed on the thin polyimide dielectric layer.

2. The power module of claim 1, wherein each of the first and second switches comprises a local gate driver disposed on the PCB between adjacent first switches or adjacent second switches.

3. The power module of claim 2, wherein the PCB comprises supporting layers disposed on opposite sides of the thin polyimide dielectric layer between the plurality of paired switches, the local gate drivers disposed on the supporting layers.

4. The power module of claim 3, wherein the supporting layers comprise polyimide.

5. The power module of claim 1, wherein the plurality of paired switches are disposed on the thin polyimide dielectric layer in a rectangular array.

6. The power module of claim 1, wherein the plurality of paired switches are mounted to the PCB using high temperature soldering.

7. The power module of claim 6, wherein the plurality of paired switches are coupled to the first and second cooling plates by low temperature soldering.

8. The power module of claim 1, wherein the power module is potted with silicone gel.

9. The power module of claim 1, wherein the first and second cooling plates are metalized ceramic cooling plates.

10. The power module of claim 9, wherein the first and second cooling plates are liquid cooled.

11. The power module of claim 1, wherein the parasitic flying capacitor elements are metallic plates embedded in the thin polyimide dielectric layer.

12. The power module of claim 1, wherein the plurality of paired switches comprise high power silicon carbide (SiC) switches.

13. The power module of claim 12, wherein adjacent paired switches are separated by a distance in a range from about 0.1 mm to about 0.2 mm.

14. The power module of claim 1, wherein the plurality of paired switches are connected in parallel, in series, or a combination of parallel and series connections.

15. The power module of claim 1, wherein a thickness of the thin polyimide dielectric layer is in a range between about 0.05 mm and about 0.15 mm.

16. The power module of claim 1, wherein the plurality of paired switches comprise N paired switches including 2N power semiconductor switches disposed on opposite sides of the polyimide dielectric layer.

17. The power module of claim 16, wherein the 2N power semiconductor switches comprise silicon carbide (SiC) devices.
